(19) United States
(12) Patent Application Publication
(10) Pub. No.: US 2025/0160130 A1
(43) Pub. Date: May 15, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wei XIA, Beijing (CN); Peng HOU, Beijing (CN); Yanqiang WANG, Beijing (CN)

(21) Appl. No.: 18/833,958

(22) PCT Filed: Nov. 9, 2023
(86) PCT No.: PCT/CN2023/130615

§ 371 Date: Jul. 29, 2024

(30) Foreign Application Priority Data
Dec. 26, 2022 (CN) 202211679923.5

(51) Int. Cl. H10K 59/122; H10K 59/124; H10K 59/80

(52) U.S. Cl. CPC H10K 59/122; H10K 59/124; H10K 59/8792

(57) ABSTRACT

Provided is a display panel. The display panel includes: a substrate; a pixel circuit layer, a planarization layer, a black pixel definition layer, an encapsulation layer, and a black matrix layer that are disposed on a side of the substrate and sequentially laminated along a direction away from the substrate; light-emitting elements in the plurality of first openings; and filter layers in the plurality of second openings, wherein a color of each of the filter layers in the plurality of second openings is the same as a color of each of the light-emitting elements in the plurality of first openings, and a transmittance of the planarization layer is not greater than a transmittance of the black pixel definition layer.

This application is a U.S. national stage of international application No. PCT/CN2023/130615, filed on Nov. 9, 2023, which claims priority to Chinese Patent Application No. 202211679923.5, filed on Dec. 26, 2022 and entitled “DISPLAY PANEL AND DISPLAY DEVICE,” the disclosures of which are herein incorporated by references in their entireties.

### TECHNICAL FIELD

The present disclosure relates to the field of display technologies, and in particular, relates to a display panel and a display device.

### BACKGROUND

For a display panel, the polarizer-less (POL-Less) technology refers to a technology of replacing a traditional polarizer in the display panel with a color film or a color filter (CF), and has merits of improving a transmittance of the display panel, reducing power consumption of the display panel, and thinning the display panel, and the like.

### SUMMARY

A display panel and a display device are provided. The technical solutions are as follows.

In some embodiments of the present disclosure, a display panel is provided. The display panel includes:
a substrate;
a pixel circuit layer, a planarization layer, a black pixel definition layer, an encapsulation layer, and a black matrix layer that are disposed on a side of the substrate and sequentially laminated along a direction away from the based substrate, wherein a plurality of first openings are defined in the black pixel definition layer, and a plurality of second openings are defined in the black matrix layer, wherein the plurality of first openings and the plurality of second openings are spaced apart along a direction parallel to a bearing face of the substrate, and the plurality of first openings are in one-to-one correspondence with the plurality of second openings;
light-emitting elements in the plurality of first openings; and
filter layers in the plurality of second openings, wherein a color of each of the filter layers in the plurality of second openings is the same as a color of each of the light-emitting elements in the plurality of first openings, and
a transmittance of the planarization layer is not greater than a transmittance of the black pixel definition layer.

In some embodiments, the planarization layer is a black planarization layer.

In some embodiments, a material of the black planarization layer is the same as a material of the black pixel definition layer.

In some embodiments, the material of the black planarization layer and the material of the black pixel definition layer both includes a carbon black additive.

In some embodiments, an optical density of the planarization layer is greater than or equal to an optical density threshold, wherein the optical density threshold is greater than an optical density of the black pixel definition layer.

In some embodiments, the optical density threshold is 3.

In some embodiments, a material of the planarization layer includes at least one of an organic material or an inorganic material, wherein the organic material is doped with a light-absorbing pigment.

In some embodiments, the inorganic material includes molybdenum oxide or aluminum oxide.

In some embodiments, the organic material includes polyimide or acrylic.

In some embodiments, the planarization layer includes a plurality of planarization film layers sequentially laminated along the direction away from the based substrate,
wherein a transmittance of at least one of the plurality of planarization film layers is not greater than the transmittance of the black pixel definition layer.

In some embodiments, the at least one of the plurality of planarization film layers includes a planarization film layer, close to the black pixel definition layer, in the plurality of planarization film layers.

In some embodiments, a thickness of the planarization layer is greater than a thickness of the black pixel definition layer, and a thickness direction is perpendicular to the bearing face of the substrate.

In some embodiments, the filter layers include color filters.

In some embodiments, the pixel circuit layer includes an active layer, a gate metal layer, and a source and drain metal layer that are sequentially laminated along the direction away from the based substrate; and the display panel further includes:
a first insulative layer between the active layer and the gate metal layer;
a second insulative layer between the gate metal layer and the source and drain metal layer;
a buffer layer between the substrate and the pixel circuit layer; and
an overcoat layer on a side, away from the substrate, of the black matrix layer.

In some embodiments of the present disclosure, a display device is provided. The display device includes: a drive circuit, and the display panel in the above embodiments;
wherein the drive circuit is electrically connected to the display panel and is configured to drive the display panel to emit light.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a display panel according to some embodiments of the present disclosure;

FIG. 2 is a schematic diagram of a slope region in a black pixel definition layer in the display panel shown in FIG. 1;

FIG. 3 is a schematic structural diagram of a display panel according to some embodiments of the present disclosure;

FIG. 4 is a schematic structural diagram of a display panel according to some embodiments of the present disclosure; and

FIG. 5 is a schematic structural diagram of a display device according to some embodiments of the present disclosure.

### DETAILED DESCRIPTION

For clearer descriptions of the objects, technical solutions, and advantages of the embodiments of present disclosure, the embodiments of the present disclosure are described in detail hereinafter in combination with the accompanying drawings.

Currently, common POL-Less technologies include a technology of integrating CF in an encapsulation layer (color on encapsulation, COE), and a display panel using the COE is referred to as a COE panel. The COE panel generally includes a substrate, and a pixel circuit layer, a pixel definition layer, an encapsulation layer, and a black matrix layer that are disposed on a side of the substrate and sequentially laminated. The pixel definition layer is configured to separate light-emitting elements of different colors. The black matrix layer is configured to separate CFs corresponding to the light-emitting element of different colors. The pixel circuit layer is configured to drive the light-emitting element to emit light, and light emitted by the light-emitting elements is transmitted upon filtering by the CFs, such that the COE panel displays color pictures.

However, researches show that external light (for example, ambient light) is prone to reflection on the current COE panel, such that chaotic color separation occurs on the COE panel, and a display effect of the COE panel is affected.

Based on description in the BACKGROUND, it can be seen that although the COE panel has low consumed power, high color gamut, and strong controllability, the COE panel is prone to color separation, and the color separation is especially obvious in the case that the COE panel displays dark state screens. The color separation is caused by several reasons. For example, the black matrix layer in the current COE panel all has patterned pixel apertures, the pixel apertures are prone to aperture diffraction, irregular reflected light is generated in the case that the external light, such as the ambient light, irradiates to the COE panel through the pixel aperture, and thus the chaotic color separation occurs on the COE panel in the case that the reflected light emits again through the pixel aperture. Currently, attempts are made to increase an anode area of the light-emitting elements in the COE panel to block emission of chaotic light, whereas the setting is not conducive to the design of the display panel with high PPI. PPI is the pixel density unit, which is called pixels per inch.

Embodiments of the present disclosure provide a display panel, which can efficiently block the reflected light and improve the color separation of the display panel without affecting the design of the display panel with high PPI.

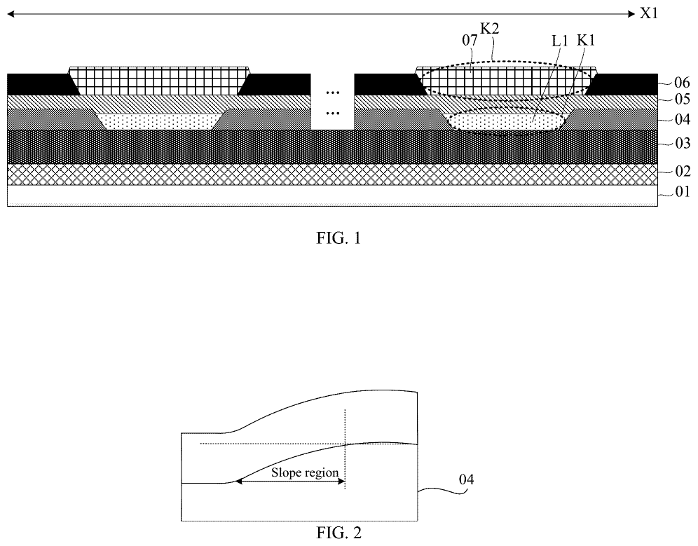

FIG. 1 is a schematic structural diagram of a display panel according to some embodiments of the present disclosure. As shown in FIG. 1, the display panel includes:

a substrate 01, and a pixel circuit layer 02, a planarization layer (PLN) 03, a black pixel definition layer (BPDL) 04, an encapsulation layer 05, and a black matrix layer (BM) 06 that are disposed on a side of the substrate 01 and sequentially laminated along a direction away from the based substrate 01. The encapsulation layer 05 is a thin film encapsulation (TFE) layer, that is, a thin film is used to encapsulate.

A plurality of first openings K1 are defined in the black pixel definition layer 04, and a plurality of second openings K2 are defined in the black matrix layer 06. The plurality of first openings K1 and the plurality of second openings K2 are spaced apart along a direction parallel to a bearing face of the substrate 01, and the plurality of first openings K1 are in one-to-one correspondence with the plurality of second openings K2.

On this basis, referring to FIG. 2, the display panel further includes: a light-emitting element L1 in each of the plurality of first openings K1, and a filter layer 07 in each of the plurality of second openings K2. That is, light-emitting elements L1 in different first openings K1 are spaced apart by the black pixel definition layer 04, and filter layers 07 in different second openings K2 are spaced apart by the black matrix layer 06.

A color of each of the filter layers 07 in the plurality of second openings K2 is the same as a color of each of the light-emitting elements L1 in the plurality of first openings K1. For example, in the case that a light-emitting element L1 in a first opening K1 is a red light-emitting element L1, a color of a filter layer 07 in a second opening K2 corresponding to the first opening K1 is red.

In addition, in some embodiments of the present disclosure, colors of light-emitting elements L1 in adjacent first openings K1 are different, and colors of filter layers 07 in adjacent second openings K2 are accordingly different. In addition, the color of the light-emitting element L1 refers to a color of light emitted by the light-emitting element L1. For example, the display panel includes a plurality of red light-emitting elements, a plurality of green light-emitting elements, and a plurality of blue light-emitting elements, and a red light-emitting element, a green light-emitting element, and a blue light-emitting element are sequentially disposed in three adjacent first openings K1. In some embodiments, colors of the light-emitting elements L1 in adjacent first openings K1 are the same, and arrangement of the plurality of light-emitting elements L1 is not limited in the embodiments of the present disclosure.

In some embodiments of the present disclosure, the pixel circuit formed in the pixel circuit layer 02 runs through the via in the planarization layer 03 to be electrically connected to the light-emitting element L1, and is configured to drive the light-emitting element L1 to emit light. For example, in the case that the light-emitting element L1 is an organic light-emitting diode (OLED), the pixel circuit transmits a drive circuit to the light-emitting element L1 to drive the light-emitting element L1 to emit light. Light emitted by the light-emitting element L1 is filtered by the filter layer 07 and is then emitted, such that the display panel displays the screen. As a polarizer is not required, the display panel is the COE panel described in the above embodiments.

It should be noted that the pixel circuit layer 02 for forming the pixel circuit generally includes a metal material. Correspondingly, the reflected light in the above embodiments refers to light reflected by the metal in the pixel circuit layer 02 in the display panel upon irradiation of the external light to the display panel.

In the embodiments of the present disclosure, a transmittance of the planarization layer 03 in the display panel is not greater than (that is, less than or equal to) a transmittance of the black pixel definition layer 04.

The black pixel definition layer 04 has a light blocking effect due to the black characteristic. In general, for 1000 nit incident light, only 100 nit light passes through the black pixel definition layer 04. Thus, the transmittance of the planarization layer 03 is less than or equal to the transmittance of black pixel definition layer 04, such that the planarization layer 03 also has the same light blocking effect as the black pixel definition layer 04. That is, in the embodiments of the present disclosure, double block for the incident light is achieved by combining the black pixel definition layer 04 with the planarization layer 03. Furthermore, the reflection for the external light by the metal in the pixel circuit layer 02 is reduced, the color separation of the display panel is improved, and the display effect of the display panel is ensured.

In addition, as the first openings K1 are defined in the black pixel definition layer 04, the black pixel definition layer 04 has a long slope region shown in FIG. 2. A transmittance of the slope region is great. That is, the slope region affects a light blocking performance of the black pixel definition layer 04. In addition, although the black pixel definition layer 04 has the light blocking effect, the black pixel definition layer 04 still has a strong transmittance in the red light of visible light due to material particularity, and thus may not achieve effective absorption of full waveband visible light from 380 nanometers (nm) to 780 nm. That is, the full waveband visible light is not effectively blocked. In the embodiments of the present disclosure, the planarization layer 03 have the same light blocking effect as the black pixel definition layer 04, such that the double block for the light is achieved as described in the above embodiments, and the problem that light may not be effectively blocked due to the high transmittance of the slope region of the black pixel definition layer 04 and the problem that the black pixel definition layer 04 may not effectively block the full waveband visible light are solved. That is, the reliable block of light is ensured, such that the color separation of the display panel is greatly improved, and the display effect of the display panel is great.

In summary, the embodiments of the present disclosure provide a display panel. The display panel includes the substrate, and the pixel circuit layer, the planarization layer, the black pixel definition layer, the encapsulation layer, and the black matrix layer that are laminated along the direction away from the based substrate. The plurality of spaced first openings are defined in the black pixel definition layer to dispose the light-emitting elements. The plurality of spaced second openings are defined in the black matrix layer to dispose the filter layer. The pixel circuit layer drives the light-emitting elements to emit light, and light emitted by the light-emitting elements is filtered by the filter layer and then is emitted, such that the display panel displays the screen. Thus, the display panel is the COE panel without the polarizer. As the transmittance of the planarization layer is not greater than the transmittance of the black pixel definition layer, the double light blocking effect is achieved by the black pixel definition layer and the planarization layer, such that the external light is prevented from irradiating to the display panel and being reflected, the color separation of the display panel is improved, and the display effect is great.

In some optional embodiments, similar to the black pixel definition layer 04, the planarization layer 03 in the embodiments of the present disclosure is a black planarization layer (BPLN). That is, in the embodiments of the present disclosure, the BPDL and the BPLN are combined to achieve efficient block for the light, such that the light blocking effect is great, the reflection of the metal in the pixel circuit layer 02 for the incident light is reduced, and the color separation of the display panel is efficiently improved.

In some embodiments, in the case that the planarization layer 03 is the black planarization layer, a material of the black planarization layer 03 is the same as a material of the black pixel definition layer 04.

For example, the material of the black planarization layer 03 and the material of the black pixel definition layer 04 both includes a carbon black additive. Based on the embodiments, the transmittance of the planarization layer 03 is equal to the transmittance of the black pixel definition layer 04.

In conjunction with FIG. 2, as the planarization layer 03 does not include the long slope region in the black pixel definition layer 04, any position of the planarization layer 03 achieves the efficient block for the light compared with the black pixel definition layer 04, such that the light blocking effect of the planarization layer 03 is greater.

In some optional embodiments, an optical density (OD) of the planarization layer 03 in the embodiments of the present disclosure is greater than or equal to an optical density threshold, and the optical density is also referred to as an absorbance. That is, the planarization layer 03 in the embodiments of the present disclosure is a high OD film layer. In some embodiments, the optical density threshold is greater than an optical density of the black pixel definition layer. Correspondingly, based on the embodiments, the transmittance of the planarization layer 03 is less than the transmittance of the black pixel definition layer 04.

The greater the optical density, the less the transmittance, the greater the light blocking effect. Thus, as the planarization layer 03 is a high OD film layer, the efficient block for the light is greatly achieved, the reflection of the metal in the pixel circuit layer 02 for the incident light is greatly reduced, and the color separation of the display panel is greatly improved.

In some embodiments, the optical density threshold is 3. That is, the OD of the planarization layer 03 is greater than or equal to 3. The test result shows that the transmittance is controlled at a value less than 0.1% in the case that the OD value of the planarization layer 03 is greater than or equal to 3. For example, assuming that for 1000 nit incident light, only 1 nit light passes through the planarization layer 03, and then it can be seen combined with the above embodiments that the planarization layer 03 with the high OD has a greater light blocking effect than the black pixel definition layer 04 which causes 100 nit light in the 1000 nit incident light to pass through the black pixel definition layer 04.

Optionally, the material of the planarization layer 03 with the high OD includes at least one of an organic material or an inorganic material, and the organic material is doped with a light-absorbing pigment to achieve a high OD.

For example, the inorganic material includes insulative molybdenum oxide (MoOx) or aluminum oxide (AlOx), and the organic material includes polyimide (PI) or acrylic.

The above optional embodiments may be combined. That is, the planarization layer 03 is the black planarization layer, and the planarization layer 03 is the high OD film layer, such that the efficient block for the light is greatly achieved, the light blocking effect is greater, the color separation of the display panel is greatly improved, and the display effect of the display panel is ensured.

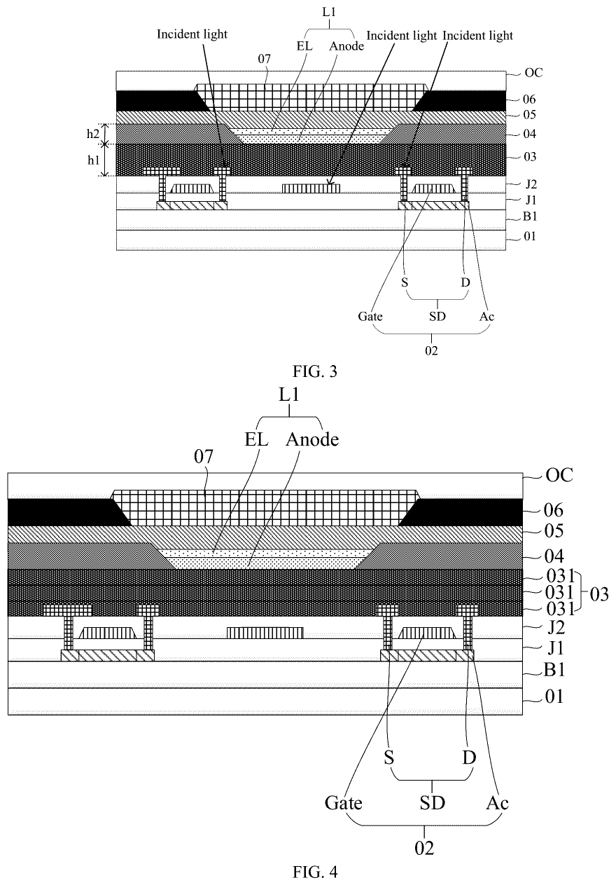

In some embodiments, FIG. 3 is a schematic structural diagram of a display panel according to some embodiments of the present disclosure. As shown in FIG. 3, the pixel circuit layer 02 includes an active layer (Ac), a gate metal layer (Gate), and a source and drain metal layer (SD) that are sequentially laminated along the direction away from the based substrate 01. The SD includes spaced source(S) and source (D). On this basis, it can be seen in conjunction with FIG. 3 that reflection of the metal in the pixel circuit layer 02 for the incident light refers to reflection of the Gate and/or the SD in the pixel circuit layer 02 for the incident light. The display panel in the embodiments of the present disclosure further includes:
a first insulative layer (J1) between the Ac and the Gate;
a second insulative layer (J2) between the Gate and the SD;
a buffer layer (B1) between the substrate 01 and the pixel circuit layer 02; and
an overcoat layer (OC) on a side, away from the substrate 01, of the black matrix layer 06.

The J1 efficiently insulates the Ac from the Gate to avoid mutual signal interference, and the J1 efficiently insulates the Gate and the SD to avoid mutual signal interference. The J1 and the J1 both are gate insulative (GI) layer. The B1 functions as buffer to protect the substrate 01. The OC is configured to protect the substrate 01 and film layers between the substrate 01 and an organic OC. In some embodiments, a material of the OC is an organic material, that is, the OC is the organic OC.

In addition, it can be seen referring to FIG. 3 that the light-emitting element L1 in the embodiments of the present disclosure includes an anode and an electro luminescence (EL) layer that are sequentially laminated along the direction away from the based substrate 01. The pixel circuit layer 02 being electrically connected to the light-emitting element L1 means that the SD in the pixel circuit layer 02 is electrically connected to the anode in the light-emitting element L1.

The light-emitting element L1 generally includes a cathode (not shown in FIG. 3) on a side, away from the substrate 01, of the EL layer. The pixel circuits formed in the pixel circuit layer 02 transmits a light-emitting drive signal to the anode in the light-emitting element L1, and the cathode in the light-emitting element L1 is electrically connected to a power terminal and receives a power signal transmitted by the power terminal. The EL layer in the light-emitting element L1 emits light under a voltage difference between the light-emitting drive signal received by the anode and the power signal received by the cathode.

In some embodiments, the substrate 01 in the embodiments of the present disclosure is a flexible substrate, and a material of the flexible substrate includes PI. In some embodiments, the substrate 01 is a non-flexible substrate. For example, the material of the substrate 01 includes glass.

In some embodiments, the filter layer 07 in the embodiments of the present disclosure includes a color filter (CF). In some embodiments, the filter layer 07 includes a color resistance, which is not limited in the embodiments of the present disclosure.

In some embodiments, it can be seen referring to FIG. 3 that a thickness h1 of the planarization layer 03 in the embodiments of the present disclosure is greater than a thickness h2 of the black pixel definition layer 04. The thickness direction is perpendicular to the bearing face of the substrate 01, that is, the thickness direction is perpendicular to the direction X1 shown in FIG. 1. By disposing the planarization layer 03 with a greater thickness, the light blocking effect is achieved, and the light blocking performance of the planarization layer 03 is further improved.

In some embodiments, it can be seen referring to FIG. 3 that in the embodiments of the present disclosure, an orthographic projection of the second opening K2 on the substrate 01 covers an orthographic projection of the first opening K1 on the substrate 01, and correspondingly, an orthographic projection of the filter layer 07 in the second opening K2 on the substrate 01 covers an orthographic projection of the light-emitting element L1 in the first opening K1 on the substrate 01, such that the efficient filtering for the light emitted by the light-emitting element L1 is ensured.

In some embodiments, FIG. 4 is a schematic structural diagram of a display panel according to some embodiments of the present disclosure. As shown in FIG. 4, the planarization layer 03 includes a plurality of planarization film layers 031 sequentially laminated along the direction away from the based substrate 01. FIG. 4 only illustratively shows three planarization film layers 031.

In the plurality of planarization film layers 031, a transmittance of at least one of the plurality of planarization film layers 031 is not greater than the transmittance of the black pixel definition layer 04. That is, in the embodiments of the present disclosure, in the case that the plurality of planarization film layers 031 are defined, one or more planarization film layers 031 have the same light blocking effect as the black pixel definition layer 04. For example, one or more planarization film layers 031 are the black planarization film layer and/or high OD film layer in the above embodiments.

In some embodiments, the at least one of the plurality of planarization film layers 031 includes a planarization film layer 031, close to the black pixel definition layer 04, in the plurality of planarization film layers 031. That is, at least the planarization film layer 031 closest to the black pixel definition layer 04 has the same light blocking effect as the black pixel definition layer 04. The transmittance of each of the planarization film layers is not greater than the transmittance of the black pixel definition layer 04. That is, each of the planarization film layers has a great light blocking effect to efficiently block the light.

It should be noted that FIG. 3 and FIG. 4 only illustratively show one first opening K1 and the corresponding second opening K2.

In summary, the embodiments of the present disclosure provide a display panel. The display panel includes the substrate, and the pixel circuit layer, the planarization layer, the black pixel definition layer, the encapsulation layer, and the black matrix layer that are laminated along the direction away from the based substrate. The plurality of spaced first openings are defined in the black pixel definition layer to dispose the light-emitting elements. The plurality of spaced second openings are defined in the black matrix layer to dispose the filter layer. The pixel circuit layer drives the light-emitting elements to emit light, and light emitted by the light-emitting elements is filtered by the filter layer and then is emitted, such that the display panel displays the screen. Thus, the display panel is the COE panel without the polarizer. As the transmittance of the planarization layer is not greater than the transmittance of the black pixel definition layer, the double light blocking effect is achieved by the black pixel definition layer and the planarization layer, such that the external light is prevented from irradiating to the display panel and being reflected, the color separation of the display panel is improved, and the display effect is great.

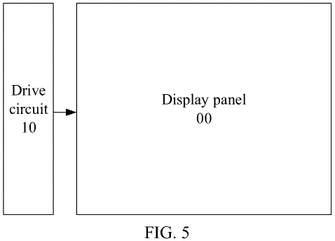

FIG. 5 is a schematic structural diagram of a display device according to some embodiments of the present disclosure. As shown in FIG. 5, the display device includes a drive circuit 10, and the display panel 100 in the above embodiments.

The drive circuit 10 is electrically connected to the display panel 100 and is configured to drive the display panel 100 to emit light.

In some embodiments, the display device in the embodiments of the present disclosure is a PLED display device, a mobile phone, a tablet computer, a flexible display device, a television, a monitor, or any other products or components with the display function.

It should be noted that in the accompanying drawings, for clarity of the illustration, the dimension of the layers and regions may be scaled up. It should be understood that when an element or layer is described as being “on” another element or layer, the described element or layer may be directly located on other elements or layers, or an intermediate layer may exist. In addition, it should be understood that when an element or layer is described as being “under” another element or layer, the described element or layer may be directly located under other elements, or more than one intermediate layer or element may exist. In addition, it should be further understood that when a layer or element is described as being arranged “between” two layers or elements, the described layer or element may be the only layer between the two layers or elements, or more than one intermediate layer or element may exist. In the whole disclosure, like reference numerals indicate like elements.

The terms used in the embodiments of the present disclosure are only used to explain the embodiments of the present disclosure, and are not intended to limit the present disclosure. Unless otherwise defined, technical or scientific terms used in the present disclosure shall have ordinary meaning understood by persons of ordinary skill in the art to which the disclosure belongs.

For example, the terms “first” and “second” are only intended to describe, and are not intended to indicate or imply relative importance. The term “a plurality of” herein means two or more, unless otherwise defined clearly.

Similarly, the terms “a,” “an,” and the like are not intended to limit the quantity, and only represent that at least one exists.

The terms “comprise” or “include” and the like are used to indicate that the element or object preceding the terms covers the element or object following the terms and its equivalents, and shall not be understood as excluding other elements or objects.

The terms “on,” “under,” “left,” and “right” are only used to indicate the relative positional relationship. When the absolute position of the described object changes, the relative positional relationship may change accordingly.

The term “and/or” herein describes associations between associated objects, and indicates three types of relationships. For example, the phrase “A and/or B” means (A), (B), or (A and B). The symbol “/” generally indicates an “or” relationship between the associated objects.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

1. A display panel, comprising:
a substrate;
a pixel circuit layer, a planarization layer, a black pixel definition layer, an encapsulation layer, and a black matrix layer that are disposed on a side of the substrate and sequentially laminated along a direction away from the substrate, wherein a plurality of first openings are defined in the black pixel definition layer, and a plurality of second openings are defined in the black matrix layer, wherein the plurality of first openings and the plurality of second openings are spaced apart along a direction parallel to a bearing face of the substrate, and the plurality of first openings are in one-to-one correspondence with the plurality of second openings;
light-emitting elements in the plurality of first openings; and
filter layers in the plurality of second openings, wherein a color of each of the filter layers in the plurality of second openings is the same as a color of each of the light-emitting elements in the plurality of first openings, and a transmittance of the planarization layer is not greater than a transmittance of the black pixel definition layer.

2. The display panel according to claim 1, wherein the planarization layer is a black planarization layer.

3. The display panel according to claim 2, wherein a material of the black planarization layer is the same as a material of the black pixel definition layer.

4. The display panel according to claim 3, wherein the material of the black planarization layer and the material of the black pixel definition layer both comprises a carbon black additive.

5. The display panel according to claim 1, wherein an optical density of the planarization layer is greater than or equal to an optical density threshold, wherein the optical density threshold is greater than an optical density of the black pixel definition layer.

6. The display panel according to claim 5, wherein the optical density threshold is 3.

7. The display panel according to claim 5, wherein a material of the planarization layer comprises at least one of an organic material or an inorganic material, wherein the organic material is doped with a light-absorbing pigment.

8. The display panel according to claim 7, wherein the inorganic material comprises molybdenum oxide or aluminum oxide.

9. The display panel according to claim 7, wherein the organic material comprises polyimide or acrylic.

10. The display panel according to claim 1, wherein the planarization layer comprises a plurality of planarization film layers sequentially laminated along the direction away from the based substrate, wherein a transmittance of at least one of the plurality of planarization film layers is not greater than the transmittance of the black pixel definition layer.

11. The display panel according to claim 10, wherein the at least one of the plurality of planarization film layers comprises a planarization film layer, close to the black pixel definition layer, in the plurality of planarization film layers.

12. The display panel according to claim 1, wherein a thickness of the planarization layer is greater than a thickness of the black pixel definition layer, and a thickness direction is perpendicular to the bearing face of the substrate.

13. The display panel according to claim 1, wherein the filter layers comprise color filters.

14. The display panel according to claim 1, wherein
the pixel circuit layer comprises an active layer, a gate metal layer, and a source and drain metal layer that are sequentially laminated along the direction away from the based substrate; and
the display panel further comprises:
a first insulative layer between the active layer and the gate metal layer;
a second insulative layer between the gate metal layer and the source and drain metal layer;
a buffer layer between the substrate and the pixel circuit layer; and
an overcoat layer on a side, away from the substrate, of the black matrix layer.

15. A display device, comprising: a drive circuit, and a display panel; wherein
the display panel comprises:
a substrate;
a pixel circuit layer, a planarization layer, a black pixel definition layer, an encapsulation layer, and a black matrix layer that are disposed on a side of the substrate and sequentially laminated along a direction away from the substrate, wherein a plurality of first openings are defined in the black pixel definition layer, and a plurality of second openings are defined in the black matrix layer, wherein the plurality of first openings and the plurality of second openings are spaced apart along a direction parallel to a bearing face of the substrate, and the plurality of first openings are in one-to-one correspondence with the plurality of second openings;
light-emitting elements in the plurality of first openings; and
filter layers in the plurality of second openings, wherein a color of each of the filter layers in the plurality of second openings is the same as a color of each of the light-emitting elements in the plurality of first openings, and a transmittance of the planarization layer is not greater than a transmittance of the black pixel definition layer; and
the drive circuit is electrically connected to the display panel and is configured to drive the display panel to emit light.

16. The display device according to claim 15, wherein the planarization layer is a black planarization layer.

17. The display device according to claim 16, wherein a material of the black planarization layer is the same as a material of the black pixel definition layer.

18. The display device according to claim 17, wherein the material of the black planarization layer and the material of the black pixel definition layer both comprises a carbon black additive.

19. The display device according to claim 15, wherein an optical density of the planarization layer is greater than or equal to an optical density threshold, wherein the optical density threshold is greater than an optical density of the black pixel definition layer.

20. The display device according to claim 19, wherein the optical density threshold is 3.
